(19) United States
(12) Patent Application Publication
(10) Pub. No.: US 2009/0242387 A1
(43) Pub. Date: Oct. 1, 2009

(54) PROCESS FOR PRODUCING SILICA GLASS CONTAINING TIO2, AND OPTICAL MATERIAL FOR EUV LITHOGRAPHY EMPLOYING SILICA GLASS CONTAINING TIO2

(75) Inventors: Akio KOIKE, Yokohama-shi (JP); Yasutomi Iwahashi, Yokohama-shi (JP); Noriaki Shimodaira, Yokohama-shi (JP); Shinya Kikugawa, Yokohama-shi (JP); Naoki Sugimoto, Yokohama-shi (JP)

Correspondence Address: OBLON, SPIVAK, MCCLELLAND MAIER & NEUSTADT, P.C., 1940 DUKE STREET, ALEXANDRIA, VA, 22314, US

(73) Assignee: ASAHI GLASS CO., LTD., Tokyo (JP)

(21) Appl. No.: 12/466,032

(22) Filed: May 14, 2009

Related U.S. Application Data
(62) Division of application No. 11/747,698, filed on May 11, 2007, now abandoned.
Application No. 11/747,698 is a continuation of application No. PCT/JP2006/300777, filed on Jan. 13, 2006.

(30) Foreign Application Priority Data
Jan. 25, 2005 (JP) 2005-016880

(51) Int. Cl. C23C 14/34

(52) U.S. Cl. 204/192.11

(57) ABSTRACT

The claimed invention relates to a process for producing an optical material for EUV lithography, wherein the optical material contains a silica glass having a TiO₂ concentration of from 3 to 12 mass % and a hydrogen molecule content of less than 5×10¹⁷ molecules/cm³ in the glass. The process including coating a multilayer film on the silica glass by ion beam sputtering.

### TECHNICAL FIELD

The present invention relates to a process for producing a silica glass containing TiO₂ (hereinafter referred to as TiO₂—SiO₂ glass) and an optical material which is TiO₂—SiO₂ glass for an exposure device of EUV lithography. In the present invention, EUV (Extreme Ultra Violet) light means light having a waveband in a soft X-ray region or in a vacuum ultraviolet region and specifically means light having a wavelength of from 0.2 to 100 nm.

### BACKGROUND ART

In recent years, in photolithography, along with high integration and high functionality of integrated circuits, microsizing of integrated circuit has been progressing. Accordingly, an exposure device is required to form an image of a circuit pattern on a wafer with a high resolution with a long focal depth, and blue shift of the exposure light source is in progress. The exposure light source has been advanced from the conventional g-line (wavelength: 436 nm), i-line (wavelength: 365 nm) or KrF excimer laser (wavelength: 248 nm), and now an ArF excimer laser (wavelength: 193 nm) is being used. Further, in order to be prepared for an integrated circuit for the next generation where the line width of a circuit pattern will be less than 100 nm, a liquid immersion technique for an exposure system for ArF excimer laser, or a technique for employing a F₂ laser (wavelength: 157 nm) as the exposure light source, is being developed. But, it is considered that even these techniques can not cover beyond a generation of a line width of 70 nm.

Under these circumstances, a lithographic technique employing a light having a wavelength of 13.5 nm among EUV light (extreme ultraviolet light) as the exposure light source, has attracted attention, as it may be applied to the printing of feature sizes of 50 nm and smaller. The image-forming principle of the EUV lithography (hereinafter referred to as “EUVL”) is the same as the conventional photolithography to such an extent that a mask pattern is transferred by means of an optical projection system. However, in the energy region of EUV light, there is no material to let the light pass therethrough. Accordingly, a refractive optical system can not be used, and an optical system will be required to be a reflective optical system in all cases.

The optical material for the exposure device to be used for EUVL is basically constituted by (1) a substrate, (2) a reflective multilayer film coated on the substrate and (3) an absorber layer formed on the reflective multilayer film. For the multilayer film, it is studied to coat layers of Mc/Si alternately. For the absorber layer, it is studied to use Ta or Cr as the layer-forming material. With regard to the substrate, a material having a low coefficient of thermal expansion is required so that expansion of substrate will cause no strain even under irradiation with EUV light. Specifically, a glass having a low thermal expansion is being studied.

TiO₂—SiO₂ glass is known to be a very low thermal expansion material having a coefficient of thermal expansion (CTE) smaller than quartz glass. Further, the coefficient of thermal expansion of TiO₂—SiO₂ glass can be controlled by the TiO₂ content in the glass. Therefore, with such TiO₂—SiO₂ glass, it is possible to obtain a zero expansion glass having a coefficient of thermal expansion being close to zero. Accordingly, TiO₂—SiO₂ glass is candidate for an optical material for EUV lithography. Further, U.S. Patent application publication No. 2002/157421 discloses a method which comprises forming a TiO₂—SiO₂ porous glass body, converting it to a glass body, and then obtaining a mask substrate therefrom.

As a conventional method for preparing TiO₂—SiO₂ glass, a method so-called a direct method has been used. In the direct method, firstly, a silica precursor and a titania precursor are, respectively, converted into a vapor form, and then mixed. Such a vapor form mixture is fed into a burner and thermally decomposed to form TiO₂—SiO₂ glass particles. Such TiO₂—SiO₂ glass particles will be deposited in a refractory container and at the same time will be melted to form TiO₂—SiO₂ glass. However, with TiO₂—SiO₂ glass prepared by this method, the temperature range in which the coefficient of thermal expansion is almost zero, has been limited to the vicinity of room temperature.

During the deposition to coat a reflection film or the like, the temperature of the optical material for an exposure device for EUVL becomes about 100° C. Further, during the exposure, the optical material will be irradiated with high energy rays, and the temperature of the optical material is likely to locally rise.

Accordingly, such an optical material for an exposure device for EUVL preferably has a wide temperature range in which the coefficient of thermal expansion is substantially zero. However, with conventional TiO₂—SiO₂ glass, the temperature range in which the coefficient of thermal expansion is substantially zero, is narrow. Therefore, such conventional glass has been inadequate for use as an optical material for an exposure device for EUVL.

On the other hand, the reflection characteristics of a reflection multilayer film depend on the density and thickness of the film. Accordingly, in order to efficiently reflect light to be used for lithography, it is necessary to precisely control the density and the thickness of the film. However, since conventional TiO₂—SiO₂ glass by a direct method is vitrified in an atmosphere containing hydrogen, hydrogen molecules are substantially contained in the glass. Accordingly, during deposition to coat a film on the glass under an ultrahigh vacuum condition, hydrogen molecules will diffuse in the chamber, and the hydrogen molecules will be taken into the film. Further, in a case where a multilayer film is coated on TiO₂—SiO₂ glass containing hydrogen molecules substantially to prepare an optical material for EUV lithography, hydrogen molecules will gradually diffuse in the film during the use, whereby a film containing hydrogen molecules will be formed. If hydrogen molecules are taken into the film, the density will be changed. Consequently, a deviation is likely to result from the optical design of the multilayer film. Further, hydrogen molecules tend to easily diffuse, and accordingly, by a change with time of the hydrogen molecule concentration, the optical characteristics of the multilayer film are likely to be changed.

### DISCLOSURE OF THE INVENTION

Embodiment 1 of the present invention provides an optical material for EUV lithography, which comprises a silica glass having a TiO₂ concentration of from 3 to 12 mass % and a hydrogen molecule content of less than 5×10¹⁷ molecules/cm³, and a multilayer film coated on the silica glass by ion beam sputtering.

Embodiment 2 of the present invention provides the optical material for EUV lithography according to Embodiment 1, wherein the silica glass has a fictive temperature of at most 1,200° C.

Embodiment 3 provides the optical material for EUV lithography according to Embodiment 1 or 2, wherein the silica glass has a CTE_{0 to 100} which means a coefficient of thermal expansion within from 0 to 100° C. of 0±150 ppb/° C.

Embodiment 4 provides the optical material for EUV lithography according to Embodiment 1, 2 or 3, wherein the homogeneity of the refractive index (Δn) of the silica glass is at most 2×10⁻⁴ within an area of 30 mm×30 mm in each of two orthogonal planes.

Embodiment 5 provides the optical material for EUV lithography according to Embodiment 1, 2, 3 or 4, wherein the fluctuation of TiO₂ concentration (ΔTiO₂) of the silica glass in the plane on which the multilayer film is coated, is at most 0.5 mass %.

Embodiment 6 provides the optical material for EUV lithography according to any one of Embodiments 1 to 5, wherein the optical material for EUV lithography is a projection mirror or a illumination mirror.

Embodiment 7 provides a process for producing a silica glass containing TiO₂, which comprises:

a step of depositing and growing, on a target, fine particles of TiO₂—SiO₂ glass obtained by flame hydrolysis of glass-forming raw materials, to form a porous TiO₂—SiO₂ glass body (porous glass body-forming step),

a step of heating the porous TiO₂—SiO₂ glass body to a densification temperature to obtain a TiO₂—SiO₂ dense body (densification step), and

a step of heating the TiO₂—SiO₂ dense body to a vitrification temperature in an atmosphere where the H₂ concentration is at most 1,000 ppm, to obtain a TiO₂—SiO₂ glass body (vitrification step).

Embodiment 8 provides the process for producing a silica glass containing TiO₂ according to Embodiment 7, which includes, after the vitrification step, a step of heating the TiO₂—SiO₂ glass body to a temperature of at least the softening point to form it into a desired shape (forming step).

Embodiment 9 provides the process for producing a silica glass containing TiO₂ according to Embodiment 7, which includes, after the vitrification step or the forming step, a step of carrying out anneal treatment which comprises holding the TiO₂—SiO₂ glass body at a temperature exceeding 500° C. for a predetermined period of time and then cooling it to 500° C. at an average cooling rate of at most 100° C./hr, or a step of carrying out anneal treatment which comprises cooling the formed glass body of at least 1,200° C. to 500° C. at an average cooling rate of at most 100° C./hr (annealing step).

According to the present invention, it is possible to obtain a low thermal expansion glass which has a wide temperature range wherein the coefficient of thermal expansion is substantially zero and which has a small content of hydrogen molecules.

### BEST MODE FOR CARRYING OUT THE INVENTION

It is known that with TiO₂—SiO₂ glass, the coefficient of thermal expansion will be changed by the concentration of TiO₂ contained. Further, at a temperature in the vicinity of room temperature, the coefficient of thermal expansion of TiO₂—SiO₂ glass containing about 7 mass % of TiO₂, is substantially zero.

The TiO₂—SiO₂ glass of the present invention is preferably a silica glass containing from 3 to 10 mass % of TiO₂. If the content of TiO₂ is less than 3 mass %, the zero expansion may not be attained. On the other hand, if it exceeds 10 mass %, the coefficient of thermal expansion may be negative. The TiO₂ concentration is more preferably from 5 to 9 mass %.

In the present invention, the hydrogen molecule content in the glass is less than 5×10¹⁷ molecules/cm³. If the hydrogen molecule content in the glass is 5×10¹⁷ molecules/cm³ or higher, the following phenomenon may occur, when a multilayer film is coated to prepare an optical material for EUV lithography. Namely, it is a phenomenon such that during deposition to coat a film under ultrahigh vacuum, hydrogen molecules in the glass will diffuse in the chamber, and the hydrogen molecules will be taken into the film, or a phenomenon such that hydrogen molecules will gradually diffuse into the film during the use, whereby a film containing hydrogen molecules will be formed.

As a result of such a phenomenon, it is possible that the density of the film will be changed, whereby a deviation from the optical design of the multilayer film will result. Otherwise, by the change with time of the hydrogen molecule concentration, the optical characteristics of the multilayer film may be changed.

The hydrogen molecule content in the glass is preferably less than 1×10¹⁷ molecules/cm³, particularly preferably less than 5×10¹⁶ molecules/cm³.

The hydrogen molecule content in the glass is measured as follows. Raman spectrometry is carried out to obtain scatter peak intensity I₄₁₃₅ at 4,135 cm⁻¹ of the laser Raman spectrum and scatter peak intensity I₈₀₀ at 800 cm⁻¹ of the fundamental vibration between silicon and oxygen. From the intensity ratio of the two (=I₄₁₃₅/I₈₀₀), the hydrogen molecule concentration (molecules/cm³) is obtained (V. S. Khotimchenko et. al., Zhurnal Prikladnoi Spektroskopii, Vol. 46, No. 6, 987-997, 1986). Here, the detection limit by this method is 5×10¹⁶ molecules/cm³.

In the present invention, the OH group concentration is preferably at most 600 wtppm. Various researches have been made with respect to the diffusion of water and the diffusion of hydrogen in silica glass (V. Lou et. al., J. Non-Cryst. Solids, Vol. 315, 13-19, 2003). According to such researches, the following equilibrium reaction is applicable to hydrogen in silica glass.

—Si—O—Si≡+H₂ [symbol] ≡SiOH+≡SiH

Hydrogen in the silica glass will be trapped by ≡Si—O—Si≡ and thereby is hardly diffusible. In a case where the OH concentration is high, however, it is considered that the effect for trapping hydrogen will be suppressed because of the equilibrium reaction, and hydrogen tends to readily diffuse and will readily be released. Further, by the above equilibrium reaction, OH in high concentration is not desirable, since it becomes a hydrogen source. The present inventors have investigated the dehydrogenation behavior in glass having a high OH concentration, whereby it has been confirmed that hydrogen is readily released by heating in vacuum. The OH group concentration is more preferably at most 400 wtppm, more preferably at most 200 wtppm, particularly preferably at most 100 wtppm.

The OH group concentration is measured as follows. A measurement by means of an infrared spectrophotometer is carried out to obtain the OH group concentration from the absorption peak at a wavelength of 2.7 μm (J. P. Williams et. al., Ceramic Bulletin, 55(5), 524, 1976). The detection limit by this method is 0.1 wtppm.

In the present invention, the coefficient of thermal expansion within from 0 to 100° C. (hereinafter referred to as CTE_{0 to 100}) is 0±150 ppb/° C. An optical material for an exposure device for EUVL or the like is required to have an extremely low coefficient of thermal expansion. If the absolute value of the coefficient of thermal expansion is 150 ppb/° C. or higher, the thermal expansion of such a material will no longer be negligible. It is preferably 0±100 ppb/° C. Likewise, the coefficient of thermal expansion within a range of from −50 to 150° C. (hereinafter referred to as CTE_{-50 to 150}) is 0±200 ppb/° C., more preferably 0±150 ppb/° C.

Further, for an optical material for an exposure device for EUVL, a coefficient of thermal expansion of glass at 22.0° C. (hereinafter referred to as CTE₂₂) is preferably 0±30 ppb/° C., more preferably 0±20 ppb/° C., further preferably 0±10 ppb/° C., particularly preferably 0±5 ppb/° C.

The coefficient of thermal expansion can be measured within a range of from −50 to 200° C. by using, for example, a laser interference type thermal expansion meter (laser expansion meter LIX-1, manufactured by ULVAC-RIKO, Inc.). To increase the precision in measuring the coefficient of thermal expansion, it is effective to carry out the measurement a plurality of times and averaging the coefficients of thermal expansion. The temperature width wherein the coefficient of thermal expansion is 0±5 ppb/° C. can be led by obtaining the temperature range wherein the coefficient of thermal expansion is from −5 to 5 ppb/° C. from the curve of the coefficient of thermal expansion obtained by the measurements.

In the present invention, the fictive temperature is at most 1,200° C. The present inventors have found that there is a relation between the fictive temperature and the width of the temperature range of zero expansion. Namely, when the fictive temperature exceeds 1,200° C., the temperature range of zero expansion tends to be narrow and inadequate as an optical material for an exposure device for EUVL. It is preferably at most 1,100° C., more preferably at most 1,000° C., particularly preferably at most 900° C.

To obtain the fictive temperature in the present invention, a method is, for example, effective wherein the silica glass is held for at least 5 hours at a temperature of from 600 to 1,200° C. and then cooled to at most 500° C. at an average cooling rate of at most 100° C./hr.

The fictive temperature is measured as follows.

With respect to mirror-polished TiO₂—SiO₂ glass, the absorption spectrum is taken by means of an infrared spectrometer (Magna760, manufactured by Nikolet). At that time, the data intervals are set to be about 0.5 cm⁻¹. For the absorption spectrum, an average value obtained by scanning 64 times will be employed. In the infrared absorption spectrum thus obtained, the peak observed in the vicinity of about 2,260 cm⁻¹, is attributable to overtone of stretching vibration due to Si—O—Si bond of TiO₂—SiO₂ glass. Using this peak position, a calibration curve is prepared by glass having the same composition, of which the fictive temperature is known, whereby the fictive temperature is obtained. Otherwise, the reflection spectrum of the surface is measured in the same manner by using a similar infrared spectrometer. In the infrared reflection spectrum thus obtained, the peak observed in the vicinity of about 1,120 cm⁻¹ is attributable to the stretching vibration due to Si—O—Si bond of TiO₂—SiO₂ glass. Using this peak position, a calibration curve is prepared by glass having the same composition, of which the fictive temperature is known, whereby the fictive temperature is obtained.

The TiO₂—SiO₂ glass of the present invention may contain F (fluorine). It is already known that the F concentration is influential over relaxing of the structure of glass (Journal of Applied Physics 91(8), 4886 (2002)). According to this report, the structural relaxing time is accelerated by F, and the glass structure having a low fictive temperature tends to be easily realized (first effect). Accordingly, to incorporate a large amount of F in the TiO₂—SiO₂ glass, is effective to lower the fictive temperature and to broaden the temperature range for zero expansion.

However, to dope F is considered to have an effect (second effect) of broadening the temperature range of zero expansion more than lowering the fictive temperature.

Further, it is considered that to dope a halogen other than F is also effective to reduce the temperature change of the coefficient of thermal expansion in the temperature range of from −50 to 150° C. and to broaden the temperature range of zero expansion with respect to the TiO₂—SiO₂ glass.

In the present invention, the Ti³⁺ concentration is at most 100 wtppm. The present inventors have found that the Ti³⁺ concentration is related to coloration, particularly to the transmittance of from 400 to 700 nm. Namely, if the Ti³⁺ concentration exceeds 100 wtppm, coloration to brown will occur. Consequently, the transmittance of from 400 to 700 nm will decrease, and there may be a trouble in the inspection or evaluation such that it becomes difficult to carry out an inspection to control the homogeneity or the surface smoothness. It is preferably at most 70 wtppm, more preferably at most 50 wtppm, particularly preferably at most 20 wtppm.

The Ti³⁺ concentration is measured by the electron spin resonance (ESR). The measurement is carried out under the following conditions.

Frequency: About 9.44 GHz (X-band)

Output: 4 mW

Modulation magnetic field: 100 KHz, 0.2 mT

Measuring temperature: Room temperature

ESR species integration range: 332 to 368 mT

Sensitivity correction: Carried out at a peak height of a predetermined amount of Mn²⁺/MgO

In the present invention, the homogeneity of the refractive index (Δn) of the silica glass is at most 2×10⁻⁴ within an area of 30 mm×30 mm in each of two orthogonal planes. The homogeneity of the refractive index in such a small area of 30 mm×30 mm is called “striae” and is caused by a fluctuation of the TiO₂—SiO₂ ratio. It is extremely important to make the TiO₂—SiO₂ ratio to be homogeneous in order to bring the glass surface to be ultrasmooth by polishing. If Δn exceeds 2×10⁻⁴, the surface after polishing can hardly be made smooth. It is preferably at most 1.5×10⁻⁴, more preferably at most 1.0×10⁻⁴, particularly preferably at most 0.5×10⁻⁴.

The homogeneity of the refractive index within an area of 30 mm×30 mm (Δn), is measured as follows. From the TiO₂—SiO₂ glass body, a cube of about 40 mm×40 mm×40 mm is, for example, cut out. Then, each side of the cube is sliced in a thickness of 1 mm to obtain a plate-shaped TiO₂—SiO₂ glass block of 30 mm×30 mm×1 mm. By a Fizeau interferometer, a helium neon laser beam is vertically irradiated to an area of 30 mm×30 mm of this glass block. The homogeneity of refractive index within the area is examined by magnifying to 2 mm×2 mm, for example, where the striae can be sufficiently observed, and the homogeneity of the refractive index (Δn) is measured.

In a case where an area of 30 mm×30 mm is directly measured, it is possible that the size of one pixel in CCD of the interferometer is not sufficiently smaller than the width of the striae, so that the striae may not be detected. Therefore, the entire area of 30 mm×30 mm is divided into a lot of small areas at a level of, for example, 2 mm×2 mm, and the Homogeneity of the refractive index (Δn₁) in each small area, is measured, and the maximum value is taken as the homogeneity of the refractive index (Δn) in an area of 30 mm×30 mm.

For example, in a case of CCD having 512×480 valid pixels, one pixel corresponds to about 4 square μm in a visual field of 2 mm×2 mm. Accordingly, striae with a pitch of at least 10 μm can be sufficiently detected, but striae smaller than this may not be detected sometime. Therefore, in a case where striae of at most 10 μm are to be measured, it is advisable to set at least that one pixel corresponds to at most 1 to 2 square μm. In Examples in this specification, the fluctuation of the refractive index (Δn₁) was measured so that one pixel corresponds to about 2 square μm by measuring an area of 2 mm×2 mm by means of CCD having 900×900 valid pixels.

By using the TiO₂—SiO₂ glass, of the present invention, it is possible to easily obtain an optical material for EUV lithography which has a small coefficient of thermal expansion and wherein the striae are not present which cause the homogeneity of the refractive index Δn to exceed 2×10⁻⁴.

Further, in the present invention, the hydrogen molecule content in the glass is small. Therefore, in the present invention, it is possible to easily obtain an optical material for EUV lithography, which is free from a change in the optical characteristics of the multilayer film by inclusion of H₂ molecules into the film or which is free from a change in the optical characteristics of the multilayer film by a change with time of the hydrogen molecule concentration in the film, in the optical material for EUV lithography to be prepared by coating the multilayer film.

As the method for deposition to coat the multilayer film, magnetron sputtering or ion beam sputtering may, for example, be used. In the magnetron sputtering, the process pressure is from 10⁻¹ to 10⁰ Pa, while in the ion beam sputtering, it is as low as from 10⁻³ to 10⁻¹ Pa. Accordingly, in the ion beam sputtering, H₂ is likely to be easily released from the glass, and even in a case where the same amount of H₂ is released from the glass, the H₂ gas concentration tends to be relatively high. Accordingly, especially in the ion beam sputtering, the hydrogen molecule content in the glass should preferably be small.

In a case where the TiO₂—SiO₂ glass of the present invention is to be used as an optical material for EUV lithography which is prepared by coating a multilayer film, it is preferred that the fluctuation of TiO₂ concentration (ΔTiO₂) in the plane irradiated with EUV light to be used for exposure, i.e. in the plane on which the multilayer film is to be coated, is at most 0.5 mass %.

In this specification, “the fluctuation of TiO₂ concentration (ΔTiO₂)” is defined to be the difference between the maximum value and the minimum value of the TiO₂ concentration in one plane.

It is very important to make the TiO₂/SiO₂ ratio homogeneous in a broad area such as an exposure area, with a view to minimizing the fluctuation of the coefficient of thermal expansion within the material. Further, such is very important also from the viewpoint of making the polishing characteristics to be homogeneous. If ΔTiO₂ exceeds 0.5 mass %, the coefficient of thermal expansion in the material is likely to have a distribution, and it tends to be difficult to attain flatness. It is preferably at most 0.3 mass %, more preferably at most 0.2 mass %, particularly preferably at most 0.1 mass %.

One example of a process for producing a TiO₂—SiO₂ glass having fluctuation of TiO₂ concentration (ΔTiO₂) controlled to be not more than 0.5 mass %, is as follows. TiO₂—SiO₂ glass particles (soot) obtained by flame hydrolysis or thermal decomposition of a Si precursor and a Ti precursor as glass-forming materials, by a soot process, are deposited and grown on a target to obtain a porous TiO₂—SiO₂ glass body. The obtained porous TiO₂—SiO₂ glass body is heated to a vitrification temperature to obtain a vitrified TiO₂—SiO₂ glass body. As the above target, a target made of quartz glass may, for example, be used.

The above process is useful, also when the homogeneity of the refractive index (Δn) is to be made at most 2×10⁻⁴ within an area of 30 mm×30 mm in each of two orthogonal planes. The present inventors have investigated the relationship between the rotational speed of the target in the step of obtaining the porous TiO₂—SiO₂ glass body and the striae of the TiO₂—SiO₂ glass body in detail. As a result, they have found that as the rotational speed of the target becomes high, the homogeneity of the refractive index in a small area in the TiO₂—SiO₂ glass body becomes small, and the striae pitch is reduced.

Specifically, in order to bring the homogeneity of the refractive index (Δn) to be at most 2×10⁻⁴ within an area of 30 mm×30 mm in each of two orthogonal planes, the rotational speed of the target at the step of forming the porous TiO₂—SiO₂ glass body is adjusted to be at least 25 rpm, more preferably at least 50 rpm, particularly preferably at least 100 rpm.

Accordingly, when the rotational speed of the target at the step of forming the porous TiO₂—SiO₂ glass body is adjusted to be at least 25 rpm, the homogeneity of the refractive index (Δn) can be made to be at most 2×10⁻⁴ within an area of 30 mm×30 mm in each of two orthogonal planes of the TiO₂—SiO₂ glass body, and the fluctuation of TiO₂ concentration (ΔTiO₂) can be made to be at most 0.5 mass %.

Further, by using the TiO₂—SiO₂ glass of the present invention, it is possible to easily obtain an optical material for EUV lithography, such as a projection mirror or a illumination mirror, which is large in volume and whereby the influence of the hydrogen molecule content in the glass is likely to appear.

The following process may be employed for producing the glass of the present invention.

### (a) Step of Forming Porous Glass Body

TiO₂—SiO₂ glass particles obtained by flame hydrolysis of a Si precursor and a Ti precursor as glass-forming materials, are deposited and grown on a target to obtain a porous TiO₂—SiO₂ glass body. The glass-forming materials are not particularly limited so long as they are materials capable of being gasified. The Si precursor may, for example, be a silicon halide compound, such as a chloride such as SiCl₄, SiHCl₃, SiH₂Cl₂ or SiH₃Cl, a fluoride such as SiF₄, SiHF₃ or SiH₂F₂, a bromide such as SiBr₄ or SiHBr₃, or an iodide such as SiI₄, or an alkoxy silane represented by RₙSi(OR)₄₋ₙ (wherein R is a C₁₋₄ alkyl group, and n is an integer of from 0 to 3). Further, the Ti precursor may, for example, be a titanium halide compound such as TiCl₄ or TiBr₄, or a titanium alkoxide represented by RₙTi(OR)₄₋ₙ (wherein R is a C₁₋₄ alkyl group, and n is an integer of from 0 to 3). Further, as the Si precursor and the Ti precursor, a compound of Si and Ti, such as a silicon-titanium double alkoxide, may also be used.

As the above target, a target made of quartz glass (such as a target disclosed in JP-B-63-24973) may be used. The target may not be limited to a rod shape, and a plate-shaped target may also be employed.

### (b) Densification Step

The porous TiO₂—SiO₂ glass body obtained by the step of forming a porous glass body, is heated to a densification temperature to obtain a TiO₂—SiO₂ dense body containing substantially no bubbles. In this specification, the densification temperature is a temperature at which the porous glass body can be densified to such an extent that void spaces can no longer be detected by an optical microscope. The densification temperature is preferably from 1,100 to 1,750° C., more preferably from 1,200 to 1,550° C.

In the case of normal pressure, the atmosphere is preferably an atmosphere of 100% inert gas such as helium or an atmosphere containing an inert gas such as helium, as the main component. In the case of reduced pressure, the atmosphere is not particularly limited.

### (c) Vitrification Step

The TiO₂—SiO₂ dense body obtained in the densification step, is heated to a vitrification temperature to obtain a TiO₂—SiO₂ glass body containing substantially no crystalline component inside.

The vitrification temperature is preferably from 1,400 to 1,800° C., more preferably from 1,500 to 1,750° C. The atmosphere is preferably the same atmosphere as in the densification step. Namely, in the case of normal pressure, it is an atmosphere of 100% inert gas such as helium or an atmosphere containing an inert gas such as helium as the main component, i.e. an atmosphere having a H₂ concentration of at most 1,000 ppm is preferred. By the atmosphere in the vitrification step, it is possible to adjust the H₂ concentration in the glass. Further, in the case of reduced pressure, the densification step and the vitrification can be carried out simultaneously.

Further, the following process may be employed to form the glass of the present invention.

### (d) Forming Step

The TiO₂—SiO₂ glass body obtained by the vitrification step, is heated to a forming temperature to obtain a formed glass body formed into a desired shape. The forming temperature is preferably from 1,500 to 1,800° C. If it is lower than 1,500° C., no substantial dead weight transformation occurs, since the viscosity of the glass is high, and growth of cristobalite as a crystalline phase of SiO₂ or growth of rutile or anatase as a crystalline phase of TiO₂ occurs, thus leading to so-called devitrification. If the temperature exceeds 1,800° C., sublimation of SiO₂ or reduction of TiO₂ may occur.

Further, the vitrification step may be omitted by subjecting the TiO₂—SiO₂ dense body obtained in the densification step to the forming step without carrying out vitrification step. Namely, in the forming step, vitrification and forming can be carried out simultaneously. Further, the atmosphere is not particularly limited.

The following process may be employed in order to control the fictive temperature by annealing of the glass of the present invention.

### (e) Annealing Step

The TiO₂—SiO₂ glass body obtained in the vitrification step or the formed glass body obtained in the forming step, is maintained at a temperature of from 600 to 1,200° C. for at least 5 hours. Then, annealing treatment is carried out by lowering the temperature to not higher than 500° C. at an average cooling rate of at most 100° C./hr, to control the fictive temperature of the glass. Otherwise, the TiO₂—SiO₂ glass body or the formed glass body which is obtained in the vitrification step or the forming step respectively, is cooled from 1,200° C. to 500° C. at an average cooling rate of at most 100° C./hr for annealing treatment to control the fictive temperature of the glass in the temperature lowering process from a temperature of at least 1,200° C. in the vitrification step or the forming step. The average cooling rate in these cases is more preferably at most 50° C./hr, further preferably at most 10° C./hr. Further, after lowering the temperature to not higher than 500° C., the glass body may be left to cool naturally. Further, the atmosphere is not particularly limited.

For the production of the glass of the present invention, other than the above process, a process may be employed wherein glass produced by a conventional direct method is maintained at a temperature of from 500° C. to 1,800° C. for from 10 minutes to 90 days in vacuum, in a reduced atmosphere or, in the case of normal pressure, in an atmosphere wherein the concentration of H₂ is at most 1,000 ppm, to carry out dehydrogenation. The dehydrogenation condition is preferably from 600° C. to 1,600° C. for one hour to 60 days, more preferably from 700° C. to 1,400° C. for 2 hours to 40 days, particularly preferably from 800° C. to 1,300° C. for 3 hours to 25 days.

Further, the atmosphere for the dehydrogenation may be one containing no H₂.

Now, the present invention will be described in further detail with reference to Examples. However, it should be understood that the present invention is by no means thereby restricted. Examples 1, 2, 4 and 5 are Examples of the present invention, and Example 3 is a Comparative Example.

### Example 1

TiO₂—SiO₂ glass particles obtained by gasifying TiCl₄ and SiCl₄ as glass-forming materials for TiO₂—SiO₂ glass, respectively, then mixing them and feeding them in oxyhydrogen flame to heat hydrolyze (flame hydrolysis) were deposited and grown on a target, to form a porous TiO₂—SiO₂ glass body having a diameter of about 80 mm and a length of about 100 mm (step of forming porous glass body).

The obtained porous TiO₂—SiO₂ glass body was difficult to handle as porous class body, and accordingly, it was held in an atmosphere of 1,200° C. for 4 hours as deposited on the target, and then removed from the target.

Then, it was held at 1,450° C. for 4 hours under reduced pressure to obtain a TiO₂—SiO₂ dense body (densification step).

The obtained TiO₂—SiO₂ dense body was held in an atmosphere of 1,650° C. for 4 hours to obtain a TiO₂—SiO₂ glass body (vitrification step).

### Example 2

TiO₂—SiO₂ glass particles obtained by gasifying TiCl₄ and SiCl₄ as glass-forming materials for TiO₂—SiO₂ glass, respectively, then mixing them and feeding them in oxyhydrogen flame to heat hydrolyze (flame hydrolysis) were deposited and grown on a target, to form a porous TiO₂—SiO₂ glass body having a diameter of about 250 mm and a length of about 1,000 mm (step of forming porous glass body).

The obtained porous TiO₂—SiO₂ glass body was difficult to handle as porous glass body, and accordingly, it was held in an atmosphere of 1,250° C. for 4 hours as deposited on the target, and then removed from the target.

Then, it was held at 1,450° C. for 4 hours under reduced pressure to obtain a TiO₂—SiO₂ dense body (densification step).

The obtained TiO₂—SiO₂ dense body was put into a carbon mold and held at 1,700° C. for 10 hours in an argon atmosphere to obtain a formed glass body containing substantially no crystalline component inside (forming step).

The obtained formed glass body was cooled from 1,200° C. to 500° C. at a rate of 100° C./hr in the cooling process in the above forming step, and then left to cool to room temperature (annealing step).

### Example 3

ULE#7972 manufactured by Corning Incorporated which is known as zero expansion TiO₂—SiO₂ glass prepared by a direct method.

### Example 4

ULE#7972 manufactured by Corning Incorporated known as zero expansion TiO₂—SiO₂ glass prepared by a direct method, was held in an atmosphere of 900° C. for 100 hours, then further held in vacuum at 900° C. for 4 hours and then quenched to control the fictive temperature (forming step).

### Example 5

ULE#7972 manufactured by Corning Incorporated known as zero expansion TiO₂—SiO₂ glass prepared by a direct method, was held in vacuum at 1,200° C. for 4 hours and then quenched to control the fictive temperature (forming step).

The results of measurements of various physical properties of the glasses prepared in Examples 1 to 5 are shown in Tables 1 and 2. The evaluation was carried out in accordance with the above-mentioned measuring methods, respectively.

TABLE 1

| | Hydrogen | | | | Homogeneity |
|---|---|---|---|---|---|
| | molecule | Fictive | OH group | Ti³⁺ | of refractive |
| | content | temperature | concentration | concentration | index Δn |
| | (molecules/cm³) | (° C.) | (wtppm) | (wtppm) | (ppm) |
| Ex. 1 | ND (<5 × 10¹⁶) | 1,160 | 40 | 2 | 50 |
| Ex. 2 | ND (<5 × 10¹⁶) | 1,020 | 40 | 7 | 300 |
| Ex. 3 | 2 × 10¹⁸ | 900 | 900 | 1 | 350 |
| Ex. 4 | ND (<5 × 10¹⁶) | 900 | 880 | 1 | 400 |
| Ex. 5 | ND (<5 × 10¹⁶) | — | — | 1 | 400 |

TABLE 2

| | | Coefficient of thermal expansion | Coefficient of thermal expansion |
|---|---|---|---|
| | Fluctuation of TiO₂ | within a range of from 0 to | within a range of from −50 to |
| | concentration in one | 100° C. CTE_{0 to 100} (ppb/° C.) | 150° C. CTE_{-50 to 150} (ppb/° C.) |
| | plane ΔTiO₂ (wtppm) | Minimum value to maximum value | Minimum value to maximum value |
| Ex. 1 | 0.1 | −60 to 140 | −250 to 175 |
| Ex. 2 | 0.3 | −80 to 130 | −270 to 165 |
| Ex. 3 | — | 15 to 110 | −110 to 115 |
| Ex. 4 | — | 30 to 145 | −105 to 145 |
| Ex. 5 | — | — | — |

Example 1 represents the glass of the present invention,

wherein the hydrogen molecule content was lower than the detection limit i.e. lower than 5×10¹⁶. Further, the fictive temperature was as low as lower than 1,200° C., and the coefficient of thermal expansion was within a range of 0±150 ppb/° C. in a temperature range of from 0 to 100° C. Further, the homogeneity of the refractive index Δn was 50 ppm, and the fluctuation of TiO₂ concentration in one plane ΔTiO₂ was 0.1 mass %. Thus, it had excellent characteristics as a glass to be used as an optical material for EUV lithography.

Example 2 represents the glass of the present invention,

wherein the hydrogen molecule content was lower than the detection limit i.e. lower than 5×10¹⁶. Further, the fictive temperature was as low as lower than 1,100° C., and the coefficient of thermal expansion was within a range of 0±150 ppb/° C. in the temperature range of from 0 to 100° C.

Example 3 represents a Comparative Example, wherein the hydrogen molecule content was high i.e. more than 5×10¹⁷ molecules/cm³.

On the other hand, in Examples 4 and 5, the hydrogen molecule content was brought to be less than 5×10¹⁷ molecules/cm³ by heat treating the same glass as in Example 3 in vacuum.

The entire disclosure of Japanese Patent Application No. 2005-016880 filed on Jan. 25, 2005 including specification, claims and summary is incorporated herein by reference in its entirety.

What is claimed is:

1. A process for producing an optical material comprising a silica glass having a TiO₂ concentration of from 3 to 12 mass % and a hydrogen molecule content of less than 5×10¹⁷ molecules/cm³, the process comprising:
coating a multilayer film on a silica glass by ion beam sputtering.

2. The process according to claim 1, wherein the ion beam sputtering is performed at a pressure of from 0.001 to 0.1 Pa.

3. The process according to claim 1, wherein the silica glass is produced by a process comprising:
depositing and growing, on a target, fine particles of TiO₂—SiO₂ glass obtained by flame hydrolysis of one or more glass-forming raw materials, to form a porous TiO₂—SiO₂ glass body (porous glass body-forming step),
heating the porous TiO₂—SiO₂ glass body to a densification temperature to obtain a TiO₂—SiO₂ dense body (densification step), and
heating the TiO₂—SiO₂ dense body to a vitrification temperature in an atmosphere where the H₂ concentration is at most 1,000 ppm, to obtain a TiO₂—SiO₂ glass body (vitrification step).

4. The process according to claim 3, wherein the process of producing the silica glass further comprises, after the vitrification step, heating the TiO₂′—SiO₂ glass body to a forming temperature of at least the softening point of the glass body to form the glass body into a desired shape (forming step).

5. The process according to claim 3, wherein the process of producing the silica glass further comprises, after the vitrification step,
carrying out an annealing treatment which comprises holding the TiO₂—SiO₂ glass body at a temperature exceeding 500° C. for a predetermined period of time and then cooling the glass body to 500° C. at an average cooling rate of at most 100° C./hr (annealing step), or
carrying out an annealing treatment which comprises cooling the formed glass body, having a temperature of at least 1,200° C., to 500° C. at an average cooling rate of at most 100° C./hr (annealing step).

6. The process according to claim 4, wherein the process of producing the silica glass further comprises, after the forming step,
carrying out an annealing treatment which comprises holding the TiO₂—SiO₂ glass body at a temperature exceeding 500° C. for a predetermined period of time and then cooling the glass body to 500° C. at an average cooling rate of at most 100° C./hr (annealing step), or
carrying out an annealing treatment which comprises cooling the formed glass body, having a temperature of at least 1,200° C., to 500° C. at an average cooling rate of at most 100° C./hr (annealing step).

7. The process according to claim 3, wherein the rotational speed of the target during the porous glass body-forming step is at least 25 rpm.

8. The process according to claim 3, wherein the densification temperature is from 1100 to 1750° C.

9. The process according to claim 3, wherein the vitrification temperature is from 1400 to 1800° C.

10. The process according to claim 4, wherein the forming temperature is from 1500 to 1800° C.

11. The process according to claim 1, wherein the silica glass has a fictive temperature of at most 1,200° C.

12. The process according to claim 1, wherein the silica glass has a coefficient of thermal expansion CTE_{0 to 100} of 0±150 ppb/° C. within from 0 to 100° C.

13. The process according to claim 1, wherein the homogeneity of the refractive index (Δn) of the silica glass is at most 2×10⁻⁴ within an area of 30 mm×30 mm in each of two orthogonal planes.

14. The process according to claim 1, wherein the fluctuation of TiO₂ concentration (ΔTiO₂) of the silica glass in the plane on which the multilayer film is coated, is at most 0.5 mass %.
